(19) United States
(12) Patent Application Publication
(10) Pub. No.: US 2023/0384355 A1
(43) Pub. Date: Nov. 30, 2023

(54) NON-INTRUSIVE LOAD MONITORING METHOD

(71) Applicant: GUANGDONG UNIVERSITY OF TECHNOLOGY, Guangzhou, Guangdong (CN)

(72) Inventors: SHENGBING XU, Guangzhou, Guangdong (CN); ZHENYOU WANG, Guangzhou, Guangdong (CN); QINTAO DU, Guangzhou, Guangdong (CN); PEIJIE LI, Guangzhou, Guangdong (CN); QINGPING DU, Guangzhou, Guangdong (CN); WEIXIAN CHEN, Guangzhou, Guangdong (CN); WEILIN CHEN, Guangzhou, Guangdong (CN)

(21) Appl. No.: 17/779,187

(22) PCT Filed: Jul. 8, 2021
(86) PCT No.: PCT/CN2021/105242

§ 371 Date: Jul. 18, 2023

(30) Foreign Application Priority Data
Aug. 27, 2020 (CN) 202010877531.4

(51) Int. Cl. G01R 19/25; G06F 18/241; G06N 20/00

(52) U.S. Cl. CPC G01R 19/2506; G01R 19/2513; G06F 18/241; G06N 20/00; G06F 2218/12

(57) ABSTRACT

A non-intrusive load monitoring system, including a device classification and prediction sub-process, a new device identification sub-process, and a classifier self-training sub-process. By means of the configuration of these processes, the defect in accuracy of identification of a new device in the prior art is overcome; and when a device other than the devices in a device database is detected, data of the device can be intercepted and stored in the device database, so that the function of accurately identifying existing devices in a device database can be achieved, and the device database can be automatically updated when a new device other than the devices in the device database is discovered.

### TECHNICAL FIELD

The present disclosure relates to the field of non-intrusive load monitoring, and in particular to a non-intrusive load monitoring method.

### BACKGROUND

Currently, the load monitoring systems studied and used in China's electric power industry are generally the intrusive load monitoring systems. However, the intrusive load monitoring system has some disadvantages, such as high application cost, difficult deployment and weak adaptability to system changes. Non-intrusive load monitoring (NILM) technology only needs to install a sensor at the user entry in the power grid. It can monitor the working state of each or every type of electrical device by collecting and analyzing the characteristics of users' electricity consumption, such as current and voltage. Hence, the NILM technology has been widely studied.

The framework of traditional NILM technology mainly includes data collection, data preprocessing, feature extraction, classifier classification and obtaining classification results. Such a system framework usually needs to establish a device database in advance. Operations such as data collection, data preprocessing, feature extraction, model training and the like are carried out on the devices in the device database to obtain a classifier model which can be used for prediction, and only the use condition of the devices included in the device database can be identified. However, in actual application, the traditional non-intrusive load monitoring system architecture has limitations. It is unable to deal with complex device replacement, changes and other situations. There is no good solution to identify new devices external to the device database, intercept the new device operation data, update the device database and retrain.

### SUMMARY

Aiming at the defects of the prior art, the disclosure provides a new non-intrusive load monitoring system. When a device other than the devices in a device database is detected, data of the device can be intercepted and stored in the device database, thereby realizing a complete system that can accurately identify existing devices in the device database and automatically updated the device database when a new device other than the devices in the device database is discovered.

For the purpose, the disclosure adopts the following technical solution: a non-intrusive load monitoring method, comprising a device classification and prediction sub-process, a new device identification sub-process, and a classifier self-training sub-process;
the new device identification sub-process comprises following steps:
step 1. making large dynamic labeling on results of transient events for detecting whether a periodic power transition device exists;
step 2. determining whether there is periodic power transition by using a peak filter method, so as to label whether the detected events have periodic changes and separate aperiodic large dynamic events from the detected events;
step 3. correcting event detection results and correcting data of stable segment to obtain possible periodic power transition device from the corrected data, and correcting prediction of electrical device again;
step 4. intercepting waveform data of stable operation segment of the electrical device, inputting the intercepted waveform data as information, calculating a number of the stable operation segments of the electrical device in a predetermined time according to recorded start time point and end time point of each transient event; wherein no electrical device is restarted between the start time point and the end time point; and labeling and recording a segment number corresponding to the start time point and the end time point;
step 5. performing feature extraction on the waveform data of the stable operation segment of each electrical device;
step 6. identifying whether an unknown device is a new device by using feature similarity discrimination index;
step 7. subtracting the waveform data of previous stable operation segment of the electrical devices from the waveform data of the stable operation segment of electrical devices having the new devices so as to separate out waveform data of the new device.

Further, before the step 1 of the new device identification sub-process, the device classification and prediction sub-process is started, and the device classification sub-process comprises following steps:
step 1. collecting and preprocessing current and voltage data of the electrical devices; wherein high-frequency current and high-frequency voltage data of multiple electrical devices in a given period of time is collected by an installed data collection terminal; and the preprocessing includes removing outliers and interpolating;
step 2. detecting event behaviors, including detecting occurrence of events and distinguishing transient event and steady state event; wherein when the event detected is classified into the transient event, the step 1 of the new device identification sub-process is performed; and when the event detected is classified into steady state event, subsequent step 3 is performed;
step 3. intercepting the preprocessed data to obtain the waveform data of the stable operation segment, performing feature extraction based on the waveform data of the stable operation segment, and extracting operating state features of the electrical device;
step 4. invoking a classifier model for prediction; wherein the operating state features of the electrical devices are used as an input of the classifier model according to the operating state features of the electrical device, and classifier model parameters generated by training are invoked for prediction;
step 5. analyzing classification results of the classifier model to obtain energy-using information of the electrical device; wherein the energy-using information comprises operating state information and energy consumption information;
wherein the classifier self-training sub-process is performed after the waveform data of the new devices is separate out in step 7 of the new devices identification sub-process;
the classifier self-training sub-process comprises following steps:
step 1. adding and updating a device database; wherein the device database comprises a device name, a device number, waveform data of steady state and transient state of each device; and for the identified new devices, a request for inputting the device name is sent to a user by a program; and finally, the device name, the device number, the waveform data of the steady state and the transient state of the new devices are automatically added into the device database;
step 2. generating waveform data of comprehensive state: generating a variety of permutations and combinations of the device number composed of different numbers by invoking the device numbers in the device database and using a calculation method of permutation and combination of the device numbers; superposing the corresponding waveform data of the devices based on the permutations and combinations of different numbers according to the obtained permutations and combinations and the waveform data of the steady state of each device in the device database, so as to obtain multiple segments of waveform data of comprehensive state superposed by different waveform data of the devices;
step 3. performing feature extraction on current waveform data during combined operation of multiple electrical devices to obtain feature data set, and dividing the obtained feature data set into a training set and a test set, and then performing parameter training by using a machine learning classifier model, as well as accurately predicting behaviors of the electrical device;
step 4. evaluating model results: statistically analyzing the prediction results of each electrical device of each cycle in n consecutive cycles within each intercepted time period of the waveform data of the stable segment of the devices, so as to determine the condition ratio of starting and stopping of the devices;
before step 7 of the new device identification sub-process, feature similarity is compared according to step 6 of the new device identification sub-process; if there is a new device, the classifier self-training sub-process is performed, and step 5 of the device classification and prediction sub-process is then performed after the model training is completed; if there is no new device, the step 5 of the device classification and prediction sub-process is directly performed to analyze which device is operating and when to start and stop it, so as to obtain the energy-using information of electrical devices.

Further, the features in the feature extraction comprise current effective value, active power and reactive power; wherein
the current effective value of the electrical device in the operating state is calculated by following equation:

$$I = \sqrt{\frac{1}{T} {\int }_{0}^{T} {i}^{2} dt} ,$$

where, I represents the current effective value, T represents the cycle and i represents instantaneous current;
the active power of the electrical device in the operating state is calculated by following equation:

P=\sqrt{3}UI cos φ,
where, P represents active power, U represents line voltage, I represents line current, and φ represents phase difference between U and I;
the reactive power of the electrical device in the operating state is calculated by following equation:

Q=\sqrt{3}UI sin φ.

Further, the step 1 of the new device identification sub-process comprises:
for the above power sequence (P₁, P₂, . . . , P_{N}), labeling the detected event with 1 and indicating that no event occurs with 0 to obtain c point sequence x[n], n∈{0, 1, 2, 3 . . . , N−1}, which is expressed as:

$$x [ n ] = \{ \begin{matrix}1 & Start point of the event \\ 0 & Other\end{matrix} .$$

Further, in the step 2 of the new device identification sub-process, non-maximum point and value that a maximum value is less than a peak value θ of the sequence obtained by Discrete Fourier Transform (DFT) is set to equal to 0 by the peak filter to obtain peak filtering effect;
wherein
for large dynamic labeled sequences x[n], performing Discrete Fourier Transform as follows:

$$X [ k ] = {\sum }_{n = 0}^{N - 1} {e}^{- i \frac{2 π}{N} nk} x [ n ] \qquad k = 0 , 1 , … , N - 1 ;$$

peak filtering is performed on the sequence obtained by DFT, and a filtering formula is as follows:

$$\hat{X} [ k ] = X [ k ] ϕ ( X [ k ] ) ψ ( \frac{{d}^{2}}{{dk}^{2}} X [ k ] ) , \\ wherein \\ ϕ ( \hat{X} [ k ] ) = \{ \begin{matrix}1 , & if \hat{X} [ k ] < θ \\ 0 , & if \hat{X} [ k ] \geq θ\end{matrix} , \\ ψ ( \frac{{d}^{2}}{{dk}^{2}} \hat{X} [ k ] ) = \{ \begin{matrix}1 , & if \frac{{d}^{2}}{{dk}^{2}} \hat{X} [ k ] < 0 \\ 0 , & if \frac{{d}^{2}}{{dk}^{2}} \hat{X} [ k ] \geq 0\end{matrix} ,$$

where, the cut-off peak value θ, in the program, adopts

$$\frac{1}{5} {X [ k ]}_{max} ,$$

the aperiodic large dynamic events is separate out obtain real events caused by starting of the devices, and to obtain steady state keys of the devices; the aperiodic large dynamic events are separate out by following steps:
performing Inverse Discrete Fourier Transform (IDFT) to \hat{X}[k] as follows:

$$\begin{matrix}\hat{x} [ n ] = \frac{1}{N} {\sum }_{k = 0}^{N - 1} {e}^{i \frac{2 π}{N} nk} \hat{X} [ k ] & n = 0 , 1 , … , N - 1\end{matrix} ;$$

Wherein separated sequence is expressed as:

η[n]=x[n]−\hat{x}[n];
the aperiodic large dynamic events meet following condition:

η[n]>η[n]ₘₐₓ.

Further, in the step 7 of the new device identification sub-process,
waveform data of the new devices after DFT is expressed as follows:

$$\begin{matrix}X [ k ] = {X}_{j} [ k ] - {X}_{j - 1} [ k ] = {\sum }_{i = 0}^{N - 1} {e}^{- i \frac{2 π}{N} nk} ( {x}_{j} [ n ] - {x}_{j - 1} [ n ] ) k \\ = 0 , 1 , … , N - 1\end{matrix} ,$$

waveform of the new devices obtained by IDFT on X[k] is expressed as follows:

$$\begin{matrix}I [ n ] = \frac{1}{N} {\sum }_{k = 0}^{N - 1} {e}^{i \frac{2 π}{N} nk} X [ k ] & n = 0 , 1 , … , N - 1\end{matrix} ,$$

where, xⱼ[n] represents waveform data of the stable operation segment of the devices in segment j.

Further, in the step 2 of the classifier self-training sub-process,
a number of household appliances in the household appliance database is set as r, and sampling points of each appliance in each cycle are c, the appliance Aⱼ is expressed as follows:

Aⱼ={I_{j,1}, I_{j,2}, . . . , I_{j,c}};
when current data of all the electrical devices operating alone is collected, current data of the multiple electrical devices is obtained through following operations:
for waveform data of the electrical device Iⱼ, model of signal waveform decomposed by Discrete time Fourier transform (DTFT) is expressed as follows:

$$\begin{matrix}{X}_{j} [ k ] = {\sum }_{n = 0}^{N - 1} {e}^{- i \frac{2 π}{N} nk} x [ n ] & k = 0 , 1 , … , N - 1\end{matrix} ;$$

when the multiple electrical devices operate simultaneously, the model of the signal waveform decomposed by DTFT is expressed as follows:

$$\begin{matrix}X [ k ] = {\sum }_{i = 0}^{s} {X}_{j} [ k ] = {\sum }_{n = 0}^{N - 1} ( {e}^{- i \frac{2 π}{N} nk} {\sum }_{i = 0}^{s} {x}_{j} [ n ] ) & k = 0 , 1 , … , N - 1\end{matrix} ;$$

where, S indicates a total number of the electrical devices simultaneously operating in combination;

X[k] is performed the IDFT as follows:

$$\begin{matrix}I [ n ] = \frac{1}{N} {\sum }_{k = 0}^{N - 1} {e}^{i \frac{2 π}{N} nk} X [ k ] & n = 0 , 1 , … , N - 1\end{matrix} ;$$

where, I[n] indicates waveform data of the multiple electrical devices operating in combination.

Further, in the step 4 of the classifier self-training sub-process, device status is evaluated as follows:
for identification results at a certain time, behaviors of each device are labeled as follows:

$$O ( t ) = \{ \begin{matrix}1 , & Device on \\ 0 , & Device off\end{matrix} ;$$

prediction results of each device within n consecutive periods are counted as follows

$$P = \frac{{\sum }_{i = 1}^{n} O ( {t}_{n} )}{n} ;$$

during this period, the real state of each device is as follows:

$$Status = \{ \begin{matrix}1 , P > p 1 \\ None , p 1 > P > p 2 \\ 0 , P < p 2\end{matrix} ;$$

wherein, when Status equals to 1, the device is started during this period; when status indicates None, the device status is unknown during this period; when status equals to 0, the device is shut down during this period; p1 represents the proportion of conditions for determining that the device is started; and p2 represents the proportion of conditions for determining that the device must not be started.

Further, the classifier is a neural network or K-means clustering algorithm or support vector machine or random forest.

Beneficial effects of the disclosure are as follows: a non-intrusive load monitoring system of an embodiment of the disclosure, comprises a device classification and prediction sub-process, a new device identification sub-process, and a classifier self-training sub-process. By means of the configuration of these method flows, the defect in accuracy of identification of a new device in the prior art is overcome; and when a device other than the devices in a device database is detected, data of the device can be intercepted and stored in the device database, so that the function of accurately identifying existing devices in a device database can be achieved, and the device database can be automatically updated when a new device other than the devices in the device database is discovered.

Specifically, the present disclosure achieves the following beneficial effects:
1) being capable of dealing with complex practical application situations and identifying periodic power transition devices;
2) improving the accuracy of determination of device behavior changes by utilizing the large dynamic markings to correctly determine the device behavior changes, so that operation data of the new devices can be intercepted more accurately;
3) making use of separated data of stable operation of devices, and performing the feature extraction and similarity comparison on it; adding the data of the new devices into an device database and retraining the new device database;
4) providing a method for determining whether a periodic transition exists in the power sequence by using the peak filter and further determining whether the periodic power transition devices exist, which can correctly determine the behavior changes of the devices, so as to intercept the operation data of the new devices more accurately.

### BRIEF DESCRIPTION OF DRAWINGS

In order to more clearly explain the embodiments of the present disclosure or the technical solutions of the prior art, the following will briefly introduce the drawings used in the description of the examples or the prior art. Obviously, the drawings in the following description are only for some examples of the disclosure, for those skilled in the art, other drawings may be obtained based on these drawings without paying any creative labor.

FIG. 1 is a flow chart of the non-intrusive load monitoring system provided by the embodiment of the present disclosure;

FIG. 2 is a schematic diagram of a device database of the composition of the non-intrusive load monitoring system provided by the embodiment of the present disclosure;

FIG. 3 is an effect diagram of a separation aperiodic large dynamic time of the non-intrusive load monitoring system provided by the embodiment of the present disclosure.

### DETAILED DESCRIPTION

The embodiment of the present disclosure provides a non-intrusive load monitoring system, which is used to automatically update the device database when a new device other than the devices in the device database is discovered. When intercepting the operation data of the new devices, it provides a method for determining whether a periodic transition exists in the power sequence by using the peak filter and further determining whether the periodic power transition devices exist, so as to intercept the operation data of the new devices more accurately.

In order to make the object, features and advantages of the present disclosure more obvious and understandable, the technical solution in the embodiments of the present disclosure will be clearly and completely described below with reference to the drawings in the embodiments of the present disclosure. Obviously, the embodiments described below are only part of the embodiments of the present disclosure, but not all of them. Based on the embodiments of the present disclosure, all other embodiments obtained by those skilled in the art without creative labor belong to the protection scope of the present disclosure.

The technical solution of the present disclosure will be further illustrated with reference to the drawings and specific embodiments.

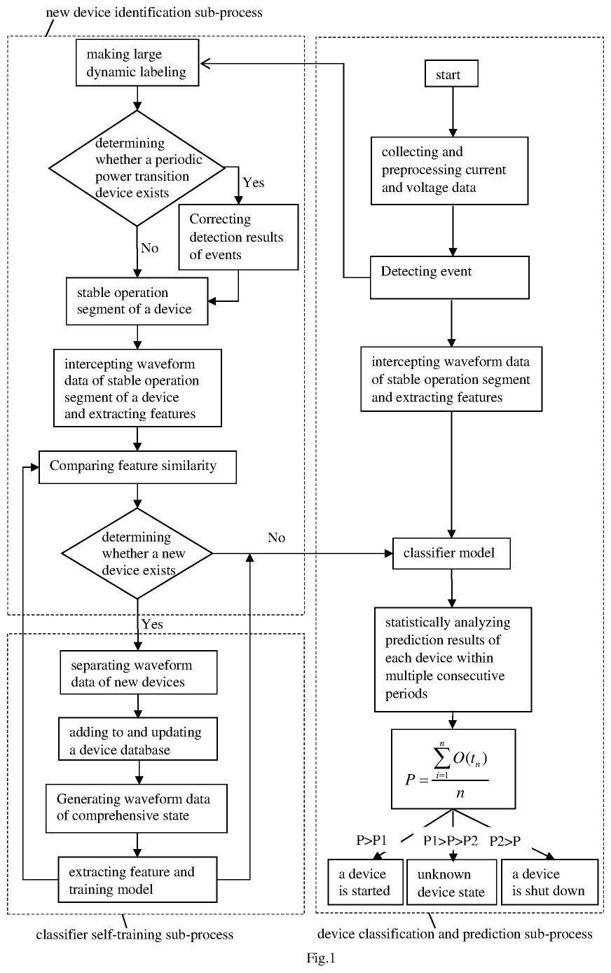

Please refer to FIG. 1, which is the flow chart of a non-intrusive load monitoring method according to the embodiment of the present disclosure. A non-intrusive load monitoring method, comprising a device classification and prediction sub-process, a new device identification sub-process, and a classifier self-training sub-process;
the new device identification sub-process comprises following steps:
step 1. making large dynamic labeling on results of transient events for detecting whether a periodic power transition device exists;
step 2. determining whether there is periodic power transition by using a peak filter method, so as to label whether the detected events have periodic changes and separate aperiodic large dynamic events from the detected events;
step 3. correcting event detection results and correcting data of stable segment to obtain possible periodic power transition device from the corrected data, and correcting prediction of electrical device again;
step 4. intercepting waveform data of stable operation segment of the electrical device, inputting the intercepted waveform data as information, calculating a number of the stable operation segments of the electrical device in a predetermined time according to recorded start time point and end time point of each transient event; wherein no electrical device is restarted between the start time point and the end time point; and labeling and recording a segment number corresponding to the start time point and the end time point;
step 5. performing feature extraction on the waveform data of the stable operation segment of each electrical device;
step 6. identifying whether an unknown device is a new device by using feature similarity discrimination index;
step 7. subtracting the waveform data of previous stable operation segment of the electrical devices from the waveform data of the stable operation segment of electrical devices having the new devices so as to extract waveform data of the new device.

Further, before the step 1 of the new device identification sub-process, the device classification and prediction sub-process is started, and the device classification sub-process comprises following steps:
step 1. collecting and preprocessing current and voltage data of the electrical devices; wherein high-frequency current and high-frequency voltage data of multiple electrical devices in a given period of time by an installed data collection terminal; and the preprocessing includes removing outliers and interpolating;
step 2. detecting event behaviors, including detecting occurrence of events and distinguishing transient event and steady state event; wherein when the event detected is classified into the transient event, the step 1 of the new device identification sub-process is performed; and
when the event detected is classified into steady state event, subsequent step 3 is performed;
step 3. intercepting the preprocessed data to obtain the waveform data of the stable operation segment, performing feature extraction based on the waveform data of the stable operation segment, and extracting operating state features of the electrical device;
step 4. invoking a classifier model for prediction; wherein the operating state features of the electrical devices are used as an input of the classifier model according to the operating state features of the electrical device, and classifier model parameters generated by training are invoked for prediction;
step 5. analyzing classification results of the classifier model to obtain energy-using information of the electrical device; wherein the energy-using information comprises operating state information and energy consumption information;
wherein the classifier self-training sub-process is performed after the waveform data of the new devices is extracted in step 7 of the new devices identification sub-process;
the classifier self-training sub-process comprises following steps:
step 1. adding and updating a device database; wherein the device database comprises a device name, a device number, waveform data of steady state and transient state of each device; and for the identified new devices, a request for inputting the device name is sent to a user by a program; and finally, the device name, the device number, the waveform data of the steady state and the transient state of the new devices are automatically added into the device database;
step 2. generating waveform data of comprehensive state: generating a variety of permutations and combinations of the device number composed of different numbers by invoking the device numbers in the device database and using a calculation method of permutation and combination of the device numbers; superposing the corresponding waveform data of the devices based on the permutations and combinations of different numbers according to the obtained permutations and combinations and the waveform data of the steady state of each device in the device database, so as to obtain multiple segments of waveform data of comprehensive state superposed by different waveform data of the devices;
step 3. performing feature extraction on current waveform data during combined operation of multiple electrical devices to obtain feature data set, and dividing the obtained feature data set into a training set and a test set, and then performing parameter training by using a machine learning classifier model, as well as accurately predicting behaviors of the electrical device;
step 4. evaluating model results: statistically analyzing the prediction results of each electrical device of each cycle in n consecutive cycles within each intercepted time period of the waveform data of the stable segment of the devices, so as to determine the condition ratio of starting and stopping of the devices;
before step 7 of the new device identification sub-process, feature similarity is compared according to step 6 of the new device identification sub-process; if there is a new device, the classifier self-training sub-process is performed, and step 5 of the device classification and prediction sub-process is then performed after the model training is completed; if there is no new device, the step 5 of the device classification and prediction sub-process is directly performed to analyze which device is operating and when to start and stop it, so as to obtain the energy-using information of electrical devices.

The following is a specific application scenario of the present disclosure:
As shown in FIG. 1, it is processed according to specific steps, and the device classification and prediction sub-process comprises the following steps:
Step 1. collecting and preprocessing current and voltage data; wherein high-frequency current and high-frequency voltage data of multiple electrical devices in a given period “time” is collected by an installed data collection terminal installed at a house entrance; and the preprocessing includes removing outliers and interpolating; the data table is as follows:

| | | Total | | |
|---|---|---|---|---|
| Device | Start time of | collection | Collected | Collected |
| name | collection | time | current data | voltage data |
| Device 1 | 06/05/2020 00:01 | Time | i₁₁, i₁₂, . . . , i₁ₙ | u₁₁, u₁₂, . . . , u₁ₙ |
| Device 2 | 06/05/2020 00:03 | Time | i₂₁, i₂₂, . . . , i₂ₙ | u₂₁, u₂₂, . . . , u₁ₙ |
| Device 3 | 06/05/2020 00:06 | Time | i₃₁, i₃₂, . . . , i₃ₙ | u₃₁, u₃₂, . . . , u₃ₙ |
| Device 4 | 06/05/2020 00:14 | Time | i₄₁, i₄₂, . . . , i₄ₙ | u₄₁, u₄₂, . . . , u₄ₙ |
| Device 5 | 06/05/2020 00:19 | Time | i₅₁, i₅₂, . . . , i₅ₙ | u₅₁, u₅₂, . . . , u₅ₙ |
| Device 6 | 06/05/2020 00:25 | Time | | u₆₁, u₆₂, . . . , u₆ₙ |
| Device 7 | 06/05/2020 00:45 | Time | i₇₁, i₇₂, . . . , i₇ₙ | u₇₁, u₇₂, . . . , u₇ₙ |
| Device 8 | 06/05/2020 00:54 | Time | i₈₁, i₈₂, . . . , i₈ₙ | u₈₁, u₈₂, . . . , u₈ₙ |
| Device 9 | 06/05/2020 00:65 | Time | i₉₁, i₉₂, . . . , i₉ₙ | u₉₁, u₉₂, . . . , u₉ₙ |

Step 2. detecting event behaviors, including detecting occurrence of events and distinguishing transient event and steady state event;
Step 3. intercepting the preprocessed data to obtain the waveform data of the stable operation segment, and extracting operating state features of the electrical device based on the waveform data of the stable operation segment;
the features in the feature extraction comprise current effective value, active power and reactive power; wherein
the current effective value of the electrical device in the operating state is calculated by following equation:

$$I = \sqrt{\frac{1}{T} {\int }_{0}^{T} {i}^{2} dt} ,$$

where, I represents the current effective value, T represents the cycle and i represents instantaneous current;
the active power of the electrical device in the operating state is calculated by following equation:

P=\sqrt{3}UI cos φ,
where, P represents active power, U represents line voltage, I represents line current, and φ represents phase difference between U and I;
the reactive power of the electrical device in the operating state is calculated by following equation:

Q=\sqrt{3}UI sin φ.
Step 4. invoking a classifier model for prediction; wherein the operating state features of the electrical devices are used as an input of the classifier model according to the operating state features of the electrical device in previous step 3, and classifier model parameters generated by training are invoked for prediction;
Step 5. analyzing the classification results of the classifier to determine which device is operating and when to start and stop it, so as to obtain the operating state and the energy consumption information of electrical devices;

The new device identification sub-process comprises following steps:
Step 1. making large dynamic labeling on results of transient events and steady state events of the device classification and prediction sub-process for detecting whether a periodic power transition device exists;
in step 2 of the device classification and prediction sub-process, event behaviors and the occurrence of events are detected; step 3 of the device classification and prediction sub-process is performed if it is distinguished as a transient event; and step 1 of large dynamic markings of the new device identification sub-process is performed if it is distinguished as a transient event;
a periodic power transition device is a device whose power can transition periodically in the process of the device operation, in particular:
for the above power sequence (P₁, P₂, . . . , P_{N}), labeling the detected event with 1 and indicating that no event occurs with 0 to obtain c point sequence x[n], n∈{0, 1, 2, 3 . . . , N−1}, which is expressed as:

$$x [ n ] = \{ \begin{matrix}1 & Start point of the event \\ 0 & Other\end{matrix}$$

Step 2. determining whether there is periodic power transition by using a peak filter method, so as to label whether the detected events have periodic changes and separate aperiodic large dynamic events from the detected events;
in the step 2 of the new device identification sub-process, non-maximum point and value that a maximum value is less than a peak value θ of the sequence obtained by Discrete Fourier Transform (DFT) is set to equal to 0 by the peak filter to obtain peak filtering effect;
wherein
for large dynamic labeled sequences x[n], performing Discrete Fourier Transform as follows:

$$X [ k ] = {\sum }_{n = 0}^{N - 1} {e}^{- i \frac{2 π}{N} nk} x [ n ] k = 0 , 1 , … , N - 1 ;$$

peak filtering is performed on the sequence obtained by DFT, and a filtering formula is as follows:

$$\hat{X} [ k ] = X [ k ] ϕ ( X [ k ] ) ψ ( \frac{{d}^{2}}{d {k}^{2}} X [ k ] ) ,$$

$$wherein$$

$$ϕ ( \hat{X} [ k ] ) = \{ \begin{matrix}1 , & if \hat{X} [ k ] < θ \\ 0 , & if \hat{X} [ k ] \geq θ\end{matrix} ,$$

$$ψ ( \frac{{d}^{2}}{{dk}^{2}} \hat{X} [ k ] ) = \{ \begin{matrix}1 , & if \frac{{d}^{2}}{{dk}^{2}} \hat{X} [ k ] < 0 \\ 0 , & if \frac{{d}^{2}}{{dk}^{2}} \hat{X} [ k ] \geq 0\end{matrix} ,$$

where, the cut-off peak value θ, in the program, adopts

$$\frac{1}{5} {X [ k ]}_{max} ,$$

the aperiodic large dynamic events is extracted to obtain real events caused by starting of the devices, and to obtain steady state keys of the devices; the aperiodic large dynamic events are extracted by following steps:
performing Inverse Discrete Fourier Transform (IDFT) to \hat{X}[k] as follows:

$$\hat{x} [ n ] = \frac{1}{N} {\sum }_{k = 0}^{N - 1} {e}^{i \frac{2 π}{N} nk} \hat{X} [ k ] n = 0 , 1 , … , N - 1 ;$$

wherein separated sequence is expressed as:

η[n]=x[n]−\hat{x}[n];
the aperiodic large dynamic events meet following condition:

η[n]>η[n]ₘₐₓ.

Note: 0.15 is a threshold in the program.

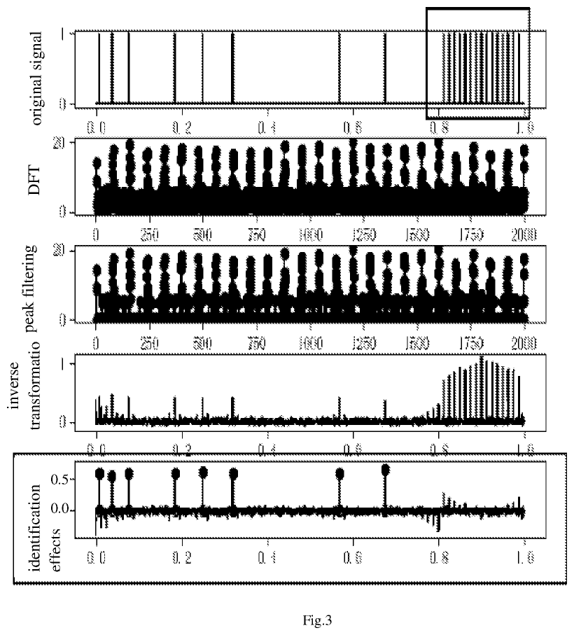

Taking active power as a research object, the aperiodic large dynamic time extracted is shown in FIG. 3:

In the identification effect subgraph, there are several obvious salient points, which are extracted aperiodic large dynamic events. Then, by comparing the results of these aperiodic large dynamic events with the original transient identification results, it can be concluded whether the device is periodic device or not. If it is consistent with the transient identification results, it means that this aperiodic large dynamic event is the transient process of the existing device; otherwise, we can consider the device as an aperiodic device.

Step 3. correcting event detection results and correcting data of stable segment to obtain possible periodic power transition device from the corrected data, and correcting prediction of electrical device again.

Without correction, the periodic power transition device may not be identified, resulting in a big difference between the combination predicted by the model and the actual combination of electrical appliances, and finally the trained model invalid. After the data of the stable segment is corrected, the data at this time is the data that all devices are in normal operation state. In this case, the interference of the current waveform changes caused by the periodic power transition device not being energized for a period of time is eliminated, and the accuracy of the prediction is enhanced. The data of each stable segment is intercepted, and the steady state waveform of each device is obtained.

Step 4. Intercepting waveform data of stable operation segment of the devices, inputting the intercepted waveform data as information, and calculating the number of stable operation segments of the electrical devices in a period of time according to recorded start time point and end time point of each transient event, that is, wherein no electrical device is restarted between the start time point and the end time point; and labeling and recording a segment number corresponding to the start time point and the end time point.

Step 5. performing feature extraction on the waveform data of the stable operation segment of each electrical device; performing feature extraction on the waveform data of stable operation segment of each device, and the feature calculation method is equivalent to the feature extraction of step 3 of the device classification and prediction process; calculating the features of different stable segments of the device, such as current effective value, active power and reactive power.

Step 6. identifying whether an unknown device is a new device by using feature similarity discrimination index;

Step 7. subtracting the waveform data of previous stable operation segment of the electrical devices from the waveform data of the stable operation segment of electrical devices having the new devices so as to extract waveform data of the new device.
waveform data of the new devices after DFT is expressed as follows:

$$X [ k ] = {X}_{j} [ k ] - {X}_{j - 1} [ k ] = {\sum }_{i = 0}^{N - 1} {e}^{i \frac{2 π}{N} nk} ( {x}_{j} [ n ] - {x}_{j - 1} [ n ] ) \\ k = 0 , 1 , … , N - 1 ,$$

waveform of the new devices obtained by IDFT on X[k] is expressed as follows:

$$I [ n ] = \frac{1}{N} {\sum }_{k = 0}^{N - 1} {e}^{i \frac{2 π}{N} nk} X [ k ] n = 0 , 1 , … , N - 1 ,$$

where, xⱼ[n] represents waveform data of the stable operation segment of the devices in segment j.

The classifier self-training sub-process comprises steps as follows:

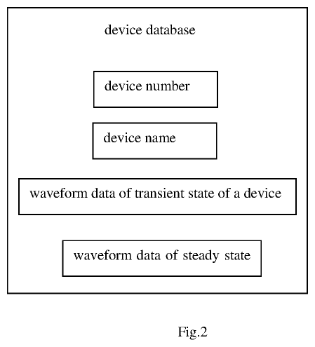

Step 1. adding and updating a device database; wherein the device database comprises a device name, a device number, waveform data of steady state and transient state of each device; and for the identified new devices, a request for inputting the device name is sent to a user by a program; and finally, the device name, the device number, the waveform data of the steady state and the transient state of the new devices are automatically added into the device database, as shown in FIG. 2,

Step 2. generating waveform data of comprehensive state: generating a variety of permutations and combinations of the device number composed of different numbers by invoking the device numbers in the device database and using a calculation method of permutation and combination of the device numbers; superposing the corresponding waveform data of the devices based on the permutations and combinations of different numbers according to the obtained permutations and combinations and the waveform data of the steady state of each device in the device database, so as to obtain multiple segments of waveform data of comprehensive state superposed by different waveform data of the devices;
in particular:
a number of household appliances in the household appliance database is set as r, and sampling points of each appliance in each cycle are c , the appliance Aⱼ is expressed as follows:

Aⱼ={I_{j,1}, I_{j,2}, . . . , I_{j,c}};
when current data of all the electrical devices operating alone is collected, current data of the multiple electrical devices is obtained through following operations.
for waveform data of the electrical device , model of signal waveform decomposed by Discrete time Fourier transform (DTFT) is expressed as follows:

$${X}_{j} [ k ] = {\sum }_{n = 0}^{N - 1} {e}^{i \frac{2 π}{N} nk} x [ n ] k = 0 , 1 , … , N - 1 ;$$

when the multiple electrical devices operate simultaneously, the model of the signal waveform decomposed by DTFT is expressed as follows:

$$X [ k ] = {\sum }_{i = 0}^{s} {X}_{j} [ k ] = {\sum }_{n = 0}^{N - 1} ( {e}^{i \frac{2 π}{N} nk} {\sum }_{i = 0}^{s} {x}_{j} [ n ] ) k = 0 , 1 , … , N - 1 ;$$

where, S indicates a total number of the electrical devices simultaneously operating in combination;
X[k] is performed the IDFT as follows:

$$I [ n ] = \frac{1}{N} {\sum }_{k = 0}^{N - 1} {e}^{i \frac{2 π}{N} nk} X [ k ] n = 0 , 1 , … , N - 1 ;$$

where, I[n] indicates waveform data of the multiple electrical devices operating in combination.

Step 3. performing feature extraction on current waveform data during combined operation of multiple electrical devices to obtain feature data set, and dividing the obtained feature data set into a training set and a test set, and then performing parameter training by using a machine learning classifier model, as well as accurately predicting behaviors of the electrical device;

Step 4. evaluating model results: statistically analyzing the prediction results of each electrical device of each cycle in n consecutive cycles within each intercepted time period of the waveform data of the stable segment of the devices, so as to determine the condition ratio of starting and stopping of the devices;
for identification results at a certain time, behaviors of each device are labeled as follows:

$$O ( t ) = \{ \begin{matrix}1 , & Device on \\ 0 , & Device off\end{matrix} ;$$

prediction results of each device within n consecutive periods are counted as follows

$$P = \frac{{\sum }_{i = 1}^{n} O ( {t}_{n} )}{n} ;$$

during this period, the real state of each device is as follows:

$$Status = \{ \begin{matrix}1 , P > p 1 \\ None , p 1 > P > p 2 \\ 0 , P < p 2\end{matrix} ;$$

wherein, when Status equals to 1, the device is started during this period; when status indicates None, the device status is unknown during this period; when status equals to 0, the device is shut down during this period; p1 represents the proportion of conditions for determining that the device is started; and p2 represents the proportion of conditions for determining that the device must not be started.

Before step 7 of the new device identification sub-process, feature similarity is compared according to step 6 of the new device identification sub-process; if there is a new device, the classifier self-training sub-process is performed, and step 5 of the device classification and prediction sub-process is then performed after the model training is completed; if there is no new device, the step 5 of the device classification and prediction sub-process is directly performed to analyze which device is operating and when to start and stop it, so as to obtain the energy-using information of electrical devices.

In conclusion, the embodiment of the disclosure discloses a non-intrusive load monitoring system, comprising a device classification and prediction sub-process, a new device identification sub-process, and a classifier self-training sub-process. By means of the configuration of these processes, the defect in accuracy of identification of a new device in the prior art is overcome; and when a device other than the devices in a device database is detected, data of the device can be intercepted and stored in the device database, so that the function of accurately identifying existing devices in a device database can be achieved, and the device database can be automatically updated when a new device other than the devices in the device database is discovered. When intercepting the operation data of the new devices, it provides a method for determining whether a periodic transition exists in the power sequence by using the peak filter and further determining whether the periodic power transition devices exist, which can correctly determine the device behavior changes, so as to intercept the operation data of the new devices more accurately.

As mentioned above, the above embodiments are only for illustrating the technical solution of the present disclosure without limiting. Although the disclosure has been described in detail with reference to the foregoing embodiments, it should be understood by those skilled in the art that it is still possible to modify the technical solutions described in the foregoing embodiments or to equivalently replace some technical features thereof without departing from the spirit and scope of the various embodiments of the present disclosure.

1. A non-intrusive load monitoring method, comprising a device classification and prediction sub-process, a new device identification sub-process, and a classifier self-training sub-process;
the new device identification sub-process comprises following steps:
step 1. making large dynamic labeling on results of transient events for detecting whether a periodic power transition device exists;
step 2. determining whether there is periodic power transition by using a peak filter method, so as to label whether the detected events have periodic changes and separate aperiodic large dynamic events from the detected events;
step 3. correcting event detection results and correcting data of stable segment to obtain possible periodic power transition device from the corrected data, and correcting prediction of electrical device again;
step 4. intercepting waveform data of stable operation segment of the electrical device, inputting the intercepted waveform data as information, calculating a number of the stable operation segments of the electrical device in a predetermined time according to recorded start time point and end time point of each transient event; wherein no electrical device is restarted between the start time point and the end time point; and labeling and recording a segment number corresponding to the start time point and the end time point;
step 5. performing feature extraction on the waveform data of the stable operation segment of each electrical device;
step 6. identifying whether an unknown device is a new device by using feature similarity discrimination index;
step 7. subtracting the waveform data of previous stable operation segment of the electrical devices from the waveform data of the stable operation segment of electrical devices having the new devices so as to separate out waveform data of the new device.

2. The non-intrusive load monitoring method according to claim 1, wherein before the step 1 of the new device identification sub-process, the device classification and prediction sub-process is started, and the device classification sub-process comprises following steps:
step 1. collecting and preprocessing current and voltage data of the electrical devices; wherein high-frequency current and high-frequency voltage data of multiple electrical devices in a given period of time is collected by an installed data collection terminal; and the preprocessing includes removing outliers and interpolating;
step 2. detecting event behaviors, including detecting occurrence of events and distinguishing transient event and steady state event; wherein when the event detected is classified into the transient event, the step 1 of the new device identification sub-process is performed; and
when the event detected is classified into steady state event, subsequent step 3 is performed;
step 3. intercepting the preprocessed data to obtain the waveform data of the stable operation segment, performing feature extraction based on the waveform data of the stable operation segment, and extracting operating state features of the electrical device;
step 4. invoking a classifier model for prediction; wherein the operating state features of the electrical devices are used as an input of the classifier model according to the operating state features of the electrical device, and classifier model parameters generated by training are invoked for prediction;
step 5. analyzing classification results of the classifier model to obtain energy-using information of the electrical device; wherein the energy-using information comprises operating state information and energy consumption information;
wherein the classifier self-training sub-process is performed after the waveform data of the new devices is separated out in step 7 of the new devices identification sub-process;
the classifier self-training sub-process comprises following steps:
step 1. adding and updating a device database; wherein the device database comprises a device name, a device number, waveform data of steady state and transient state of each device; and for the identified new devices, a request for inputting the device name is sent to a user by a program; and
finally, the device name, the device number, the waveform data of the steady state and the transient state of the new devices are automatically added into the device database;
step 2. generating waveform data of comprehensive state: generating a variety of permutations and combinations of the device number composed of different numbers by invoking the device numbers in the device database and using a calculation method of permutation and combination of the device numbers; superposing the corresponding waveform data of the devices based on the permutations and combinations of different numbers according to the obtained permutations and combinations and the waveform data of the steady state of each device in the device database, so as to obtain multiple segments of waveform data of comprehensive state superposed by different waveform data of the devices;
step 3. performing feature extraction on current waveform data during combined operation of multiple electrical devices to obtain feature data set, and dividing the obtained feature data set into a training set and a test set, and then performing parameter training by using a machine learning classifier model, as well as accurately predicting behaviors of the electrical device;
step 4. evaluating model results: statistically analyzing the prediction results of each electrical device of each cycle in n consecutive cycles within each intercepted time period of the waveform data of the stable segment of the devices, so as to determine the condition ratio of starting and stopping of the devices;
before step 7 of the new device identification sub-process, feature similarity is compared according to step 6 of the new device identification sub-process; if there is a new device, the classifier self-training sub-process is performed, and step 5 of the device classification and prediction sub-process is then performed after the model training is completed; if there is no new device, the step 5 of the device classification and prediction sub-process is directly performed to analyze which device is operating and when to start and stop it, so as to obtain the energy-using information of electrical devices.

3. The non-intrusive load monitoring method according to claim 1 or 2, wherein the features in the feature extraction comprise current effective value, active power and reactive power; wherein
the current effective value of the electrical device in the operating state is calculated by following equation:
$$I = \sqrt{\frac{1}{T} {\int }_{0}^{T} {i}^{2} dt} ,$$
where, I represents the current effective value, T represents the cycle and i represents instantaneous current;
the active power of the electrical device in the operating state is calculated by following equation:
P=\sqrt{3}UI cos φ.
where, P represents active power, U represents line voltage, I represents line current, and φ represents phase difference between U and I;
the reactive power of the electrical device in the operating state is calculated by following equation:
Q=\sqrt{3}UI sin φ.

4. The non-intrusive load monitoring method according to claim 1, wherein the step 1 of the new device identification sub-process comprises:
for the above power sequence (P₁, P₂, . . . , P_{N}), labeling the detected event with 1 and indicating that no event occurs with 0 to obtain c point sequence x[n], n∈{0, 1, 2, 3 . . . , N−1}, which is expressed as:
$$x [ n ] = \{ \begin{matrix}1 & Start point of the event \\ 0 & Other\end{matrix} .$$

5. The non-intrusive load monitoring method according to claim 1, wherein in the step 2 of the new device identification sub-process, non-maximum point and value that a maximum value is less than a peak value θ of the sequence obtained by Discrete Fourier Transform (DFT) is set to equal to 0 by the peak filter to obtain peak filtering effect;
wherein
for large dynamic labeled sequences x[n], performing Discrete Fourier Transform as follows:
$$X [ k ] = {\sum }_{n = 0}^{N - 1} {e}^{- i \frac{2 π}{N} nk} k = 0 , 1 , … , N - 1 ;$$
peak filtering is performed on the sequence obtained by DFT, and a filtering formula is as follows:
$$\hat{X} [ k ] = X [ k ] ϕ ( X [ k ] ) ψ ( \frac{{d}^{2}}{{dk}^{2}} X [ k ] ) ,$$
$$wherein$$
$$ϕ ( \hat{X} [ k ] ) = \{ \begin{matrix}1 , & if \hat{X} [ k ] < θ \\ 0 , & if \hat{X} [ k ] \geq θ\end{matrix} ,$$
$$ψ ( \frac{{d}^{2}}{{dk}^{2}} \hat{X} [ k ] ) = \{ \begin{matrix}1 , & if \frac{{d}^{2}}{{dk}^{2}} \hat{X} [ k ] < 0 \\ 0 , & if \frac{{d}^{2}}{{dk}^{2}} \hat{X} [ k ] \geq 0\end{matrix} ,$$
where, the cut-off peak value θ, in the program, adopts
$$\frac{1}{5} {X [ k ]}_{max} ,$$
the aperiodic large dynamic events is separated out to obtain real events caused by starting of the devices, and to obtain steady state keys of the devices; the aperiodic large dynamic events are separated out by following steps:
performing Inverse Discrete Fourier Transform (IDFT) to \hat{X}[k] as follows:
$$\hat{x} [ n ] = \frac{1}{N} {\sum }_{k = 0}^{N - 1} {e}^{i \frac{2 π}{N} n k} \hat{X} [ k ] n = 0 , 1 , … , N - 1 ;$$
wherein separated sequence is expressed as:
η[n]=x[n]−\hat{x}[n];
the aperiodic large dynamic events meet following condition:
η[n]>η[n]ₘₐₓ.

6. The non-intrusive load monitoring method according to claim 1, wherein in the step 7 of the new device identification sub-process,
waveform data of the new devices after DFT is expressed as follows:
$$X [ k ] = {X}_{j} [ k ] - {X}_{j - 1} [ k ] = {\sum }_{i = 0}^{N - 1} {e}^{- i \frac{2 π}{N} n k} ( {x}_{j} [ n ] - {x}_{j - 1} [ n ] ) \\ k = 0 , 1 , … , N - 1 ,$$
waveform of the new devices obtained by IDFT on X[k] is expressed as follows:
$$I [ n ] = \frac{1}{N} {\sum }_{k = 0}^{N - 1} {e}^{i \frac{2 π}{N} nk} X [ k ] n = 0 , 1 , … , N - 1 ,$$
where, xⱼ[n] represents waveform data of the stable operation segment of the devices in segment j.

7. The non-intrusive load monitoring method according to claim 2, wherein in the step 2 of the classifier self-training sub-process,
a number of household appliances in the household appliance database is set as r, and sampling points of each appliance in each cycle are c, the appliance Aⱼ is expressed as follows:
Aⱼ={I_{j,1}, I_{j,2}, . . . , I_{j,c}};
when current data of all the electrical devices operating alone is collected, current data of the multiple electrical devices is obtained through following operations:
for waveform data of the electrical device Iⱼ, model of signal waveform decomposed by Discrete time Fourier transform (DTFT) is expressed as follows:
$${X}_{j} [ k ] = {\sum }_{n = 0}^{N - 1} {e}^{- i \frac{2 π}{N} nk} x [ n ] k = 0 , 1 , … , N - 1 ;$$
when the multiple electrical devices operate simultaneously, the model of the signal waveform decomposed by DTFT is expressed as follows:
$$X [ k ] = {\sum }_{i = 0}^{s} {X}_{j} [ k ] = {\sum }_{n = 0}^{N - 1} ( {e}^{- i \frac{2 π}{N} nk} {\sum }_{i = 0}^{s} {x}_{j} [ n ] ) k = 0 , 1 , … , N - 1 ;$$
where, S indicates a total number of the electrical devices simultaneously operating in combination;
X[k] is performed the IDFT as follows:
$$I [ n ] = \frac{1}{N} {\sum }_{k = 0}^{N - 1} {e}^{i \frac{2 π}{N} nk} X [ k ] n = 0 , 1 , … , N - 1 ;$$
where, I[n] indicates waveform data of the multiple electrical devices operating in combination.

8. The non-intrusive load monitoring method according to claim 2, wherein in the step 4 of the classifier self-training sub-process,
device status is evaluated as follows:
for identification results at a certain time, behaviors of each device are labeled as follows:
$$O ( t ) = \{ \begin{matrix}1 , & Device on \\ 0 , & Device off\end{matrix} ;$$
prediction results of each device within n consecutive periods are counted as follows
$$P = \frac{{\sum }_{i = 1}^{n} O ( {t}_{n} )}{n} ;$$
during this period, the real state of each device is as follows:
$$Status = \{ \begin{matrix}1 , P > p 1 \\ None , p 1 > P > p 2 \\ 0 , P < p 2\end{matrix} ;$$
wherein, when Status equals to 1, the device is started during this period; when status indicates None, the device status is unknown during this period; when status equals to 0, the device is shut down during this period; p1 represents the proportion of conditions for determining that the device is started; and p2 represents the proportion of conditions for determining that the device must not be started.

9. The non-intrusive load monitoring method according to claim 1, wherein the classifier is a neural network or K-means clustering algorithm or support vector machine or random forest.
